(19) United States
(12) Patent Application Publication
(10) Pub. No.: US 2010/0099253 A1
(43) Pub. Date: Apr. 22, 2010

(54) Method for Structuring a Layered Stack

(76) Inventors: Ulrich Baier, Dresden (DE); Guenther Czech, Langebrueck (DE); Detlef Weber, Ottendorf-Okrilla (DE); Jean Charles Cigal, Dresden (DE); Michael Beck, Dresden (DE); Peter Lahnor, Dresden (DE); Marc Petri, Moritzburg OT Auer (DE)

Correspondence Address: SLATER & MATSIL, L.L.P., 17950 PRESTON ROAD, SUITE 1000, DALLAS, TX, 75252, US

(21) Appl. No.: 12/253,061

(22) Filed: Oct. 16, 2008

(51) Int. Cl. H01L 21/768

(52) U.S. Cl. 438/666; 257/E21.579

(57) ABSTRACT

One implementation is a method for fabricating a semiconductor on a substrate. A first layer is formed on the substrate. An implanted pattern is introduced into the first layer by implanting using a structured implantation mask arranged over the first layer. A structured second layer is formed on the first layer after removing the implantation mask. A first pattern is generated in the substrate using the second layer as a mask. The first layer is developed with regard to the implanted pattern. A second pattern is generated in the substrate using the first layer as a mask.

### TECHNICAL FIELD

The invention relates to the field of manufacturing semiconductor devices, more particular to introducing structures into a substrate for forming a semiconductor device.

### BACKGROUND

In the processing of substrates in the manufacturing of semiconductor devices in many cases more than one lithography is used to achieve, e.g., more complex structures in the substrate. For example, in a dual damascene scheme, a via structure and a trench structure are introduced into a dielectric layer using different lithography levels. The topology introduced by the structure formed first may impact the formation process of the subsequent structure. Therefore, a need exists to introduce structuring information to the substrate without or with minimal topology creation.

### SUMMARY OF THE INVENTION

A method is disclosed for fabricating a semiconductor device, wherein a first layer is formed on a substrate. An implanted pattern is introduced into the first layer by implantation using an implantation mask on the first layer. The implantation mask is removed, and a first pattern is generated in the substrate using a structured second layer. The first layer is developed with regard to the implanted pattern and acts as a mask to generate a second pattern in the substrate.

### BRIEF DESCRIPTION OF THE DRAWINGS

FIGS. 1A to 1J show different cross sections of a layered stack according to a first implementation;

FIGS. 2A to 2G show different cross sections of a layered stack according to a second implementation;

FIGS. 3A to 3G show different cross sections of a layered stack according to a third implementation;

FIGS. 4A to 4F show different cross sections of a layered stack according to a fourth implementation;

FIGS. 5A to 5D show different cross sections of a layered stack according to a fifth implementation;

FIG. 6 shows a flowchart of an implementation of the method; and

FIG. 7 shows a flowchart of a further implementation of the method.

### DETAILED DESCRIPTION OF ILLUSTRATIVE EMBODIMENTS

In the following different implementations of a method for manufacturing two patterns are described as examples. The patterns in the examples are via structures 11 and trench structures 12 as used, e.g., in a dual damascene manufacturing processes. The person skilled in the art will recognize that other patterns and other applications apart from dual damascene processes are possible.

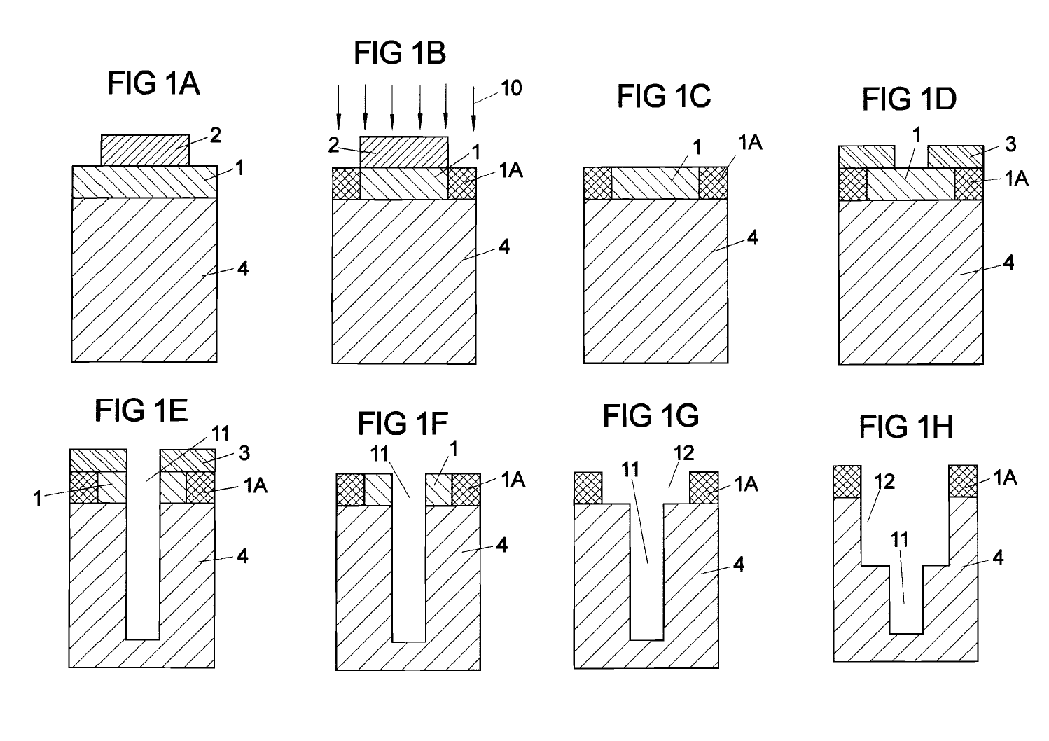

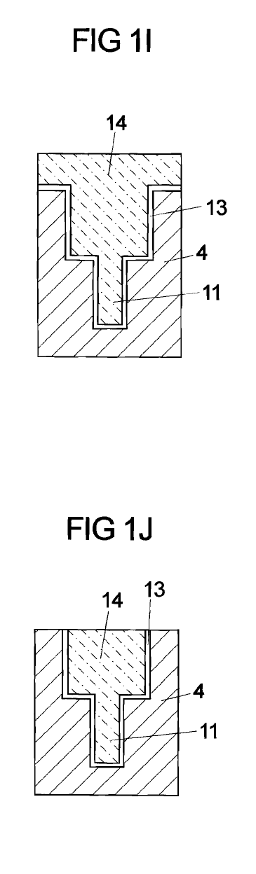

For example, a first implementation of the method in FIGS. 1A to 1H cross sections of a layered stack are shown, as the layered stack is subjected to various processes.

In FIG. 1A a starting point for the first implementation of the method is shown. The implementation of the method is applied in this case to a structure to be used in a memory chip. The person skilled in the art will recognize that this implementation, as well as the implementations described further below are applicable to the manufacturing of other semiconductor devices, such as microprocessors, optoelectronic devices, biochips or microelectromechanical devices.

The layered stack in this implementation may comprise one base layer 4 of a dielectric material like silicon oxide, low k material or other materials used as interlayer dielectrics (ILD). In other implementations, as will be shown below, the base layer 4 can comprise more layers with different materials, which also can be structured layers. In other implementations the layered stack can also comprise just one layer, e.g., as a substrate.

In the first implementation, a first layer 1 is positioned on top of the base layer 4 (FIG. 1A). The first layer 1 may comprise amorphous silicon. As will be become clear in connection with other implementations, different materials (e.g., Al₂O₃, SiN, SiON, TiN, high k materials) can be used in the first layer 1.

On top of the first layer 1, an implantation mask 2 is positioned. The implantation mask 2 comprises a resist and an optional ARC layer which in FIG. 1A is already shown as pre-structured. The implantation mask 2 can be considered as implant-sensitive. The implantation mask 2 covers the first layer 1 only partially.

As will be become clear in other implementations, different materials can be used in the implantation mask 2.

In FIG. 1B the result of a second process is depicted in which the surface of the layered stack, comprising the base layer 4, the first mask layer 1 and the second mask layer 2 are subjected to an implantation 10 into the exposed portions of layer 1. BF₂ or Xe may be used as an implantation species. The implantation 10, e.g., in the amorphous silicon results in an inclusion of the implantation species into the lattice. In other implementations the implantation 10 leads also to a change in the physical and/or chemical structure of the implanted lattice. In other words, the first mask layer 1 is an implant-sensitive layer in the meaning that the inclusion of the implanted species in and/or change of the structure of the first mask layer 1 can be used to pattern the first mask layer 1 in a subsequent development process and without a further mask, as described below.

One example of such an implant-sensitive layer can be an Al₂O₃ layer which can, e.g., be deposited by a PVD method, in which the Al₂O₃ crystallizes at low temperature. This layer is, e.g., resistant to a standard clean etch (SC1) and can be made susceptible to an attack by a standard clean etch by ion implantation. A standard clean 1 etch uses ammonia hydroxide, hydrogen peroxides and deionized water.

Depending on the choice of implant species, the etching chemistry changes. If B, BF3 or As are used, implanted Al₂O₃ can be removed by a Standard Clean 1 etch.

If O is used as an implant species, implanted Al₂O₃ can be removed with, e.g., a Standard Clean 1 etch.

Another choice of material can be a-Si. Non-implanted a-Si is, e.g., removed with NH₄OH. The amorphous silicon that is not implanted with O can, e.g., be removed with a highly selective chemistry such as, e.g., HBr/HE/O₂ or SF₆.

Depending on the choice of materials in the mask layers 1, 2, other species can be used to implant the areas of the first layer 1 which are not covered by the implantation mask 2. The implantation mask 2 absorbs the implanted species so that the first layer 1 is shielded in parts from the implantation 10.

In the first implementation the result of the process is that both implanted regions 1A and non-implanted regions 1 are generated in the first layer 1. The first layer 1 comprises a projected image of the implantation mask 2 without generating a topology on the surface, as, e.g., an etching process might do. The geometrical information of the implantation mask 2 is stored by this virtual mask, i.e., the implanted region 1A.

The structure (i.e., the virtual structure caused by the implantation 10) in the first layer 1 will later be used to generate a structure in the layered stack

In a further process (FIG. 1C) the implantation mask 2 is removed by, e.g., an etching process. After the removal, the surface of first layer 1 is essentially planar since the only structuring of the first layer 1 has been due to the implantation 10 (see FIG. 1B).

In a further process (FIG. 1D) a second layer 3 is positioned on top of the first layer 1. Since the underlying first layer 1 is essentially planar, a two mask layer system with planar layers is generated. In the present implementation the second layer 3 comprises a resist and an optional ARC layer.

In a further etching process (FIG. 1E) the second layer 3 is used as an etch mask to etch a first pattern, in this case a via structure 11 into the layered stack, i.e., especially into the base layer 4.

In FIG. 1F the layered stack of FIG. 1E is shown after the removal of the second layer 3 from the first layer 1. A selective removal of implanted layer vs. non-implanted layer, e.g., by wet etching is performed. Depending on the materials used in other implementations (examples given above in connection with FIG. 1B), the inverse process is also possible, i.e., the non-implanted layer is removed selectively to the implanted layer.

As can be seen in FIGS. 1F to 1H, the implanted region 1A of the first layer 1 is used as a mask for etching a second pattern, in the present implementation a trench structure 12 (FIG. 1H). The non implanted region of the first layer 1 is selectively removed to form a further mask comprising the implanted regions 1A.

As can be seen in this first implementation, seen in the cross section the perimeter of the first pattern, in this case a via structure 11, is surrounded by the second pattern, in this case the trench structure 12. The perimeters can be understood as the outline of the patterns 11, 12 (via structure, trench structure) which are seen perpendicular to the layered stack. As can be derived from FIG. 1G, the perimeter of the larger trench structure 12 encompasses the smaller via structure 11. Therefore, a hierarchical pattern structure is manufactured, the second pattern being larger, thereby containing the first pattern.

In other words, the first pattern 11 can comprise, e.g., openings, the second pattern 12 can comprise, e.g., lines. The lines of the second pattern 12 overlap with the openings of the first pattern 11. In one implementation, the lines might completely cover the openings.

In FIGS. 1I and 1J one possibility of a further processing is described. The starting point would be a layered stack as shown in FIG. 1H after the implanted layer 1A has been stripped off. In FIG. 1I it is shown that the first and the second pattern 11, 12 are filled with a conductive material 14. Examples of conductive materials are tungsten, copper and aluminum. As indicated in FIG. 1H, before the filling with the conductive material, a liner 13 can be deposited in the first and second pattern 11, 12. In FIG. 1J the cross section of FIG. 1I is shown after a chemical mechanical polishing (CMP) process. Thereby a metallization level is formed. The same further processing can be applied to other implementations shown below.

In an alternative implementation the implanted layer 1A is not stripped off before the filling of the first and second pattern 11, 12.

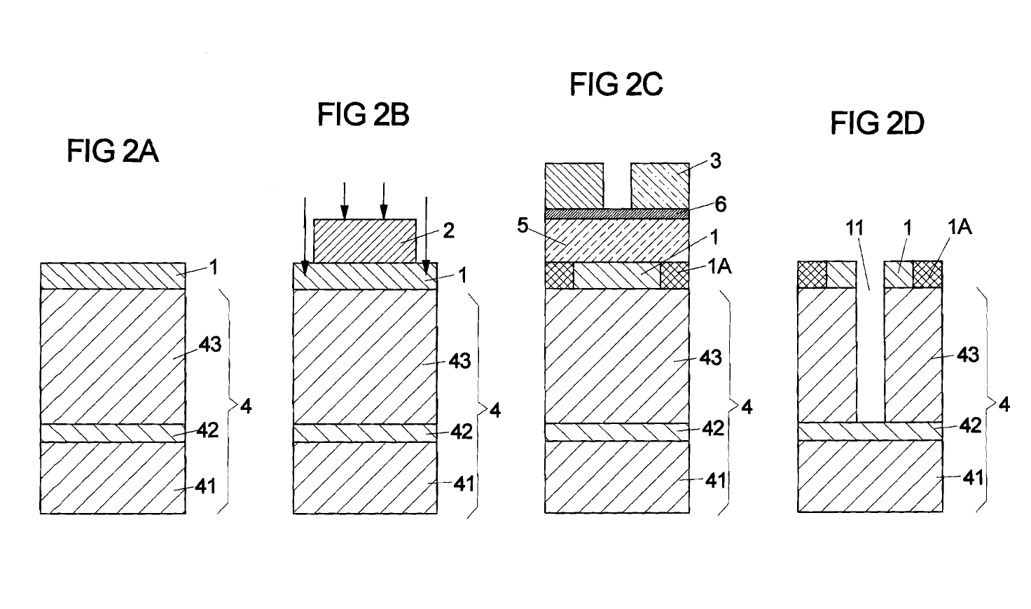

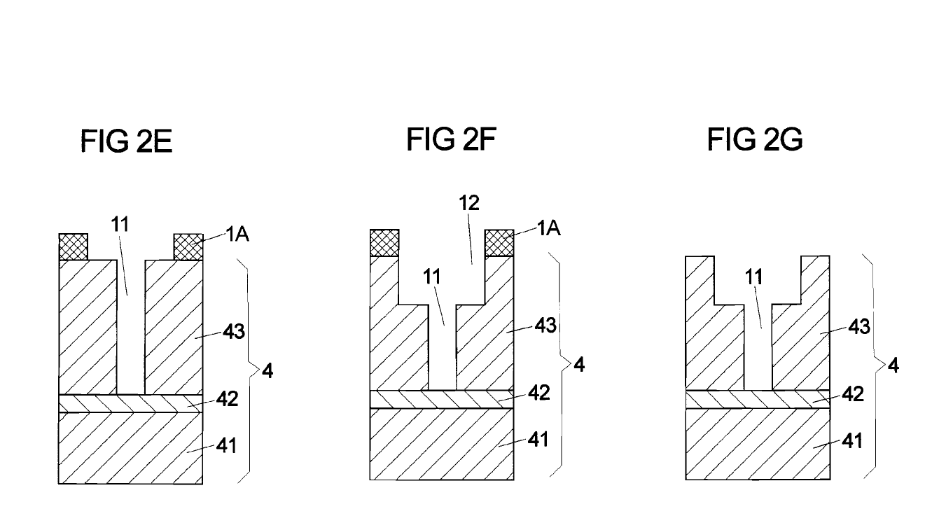

A second implementation is described in FIGS. 2A to 2G. In this example the generation of a first pattern, here a via structure 11 contacting a metal layer 41, in this case a copper line, in the base layer 4 is described. In other implementations the metal layer 41 can comprise tungsten or poly silicon.

The base layer 4 may also comprise a barrier layer 42 like SiC, among other suitable materials, above the metal layer 41. The barrier layer 42 prevents the diffusion of copper into the ILD layer 43 on top of the barrier layer.

Like in the first implementation, on top of the ILD layer 43 an amorphous silicon layer is provided as first layer 1. Alternatively the first layer 1 can comprise Al₂O₃. The implantation mask 2 on top of the first layer 1 may comprise a resist and an optional ARC layer.

In a further process (FIG. 2B) this layered stack is subjected to an implantation 10 with BF₂, as in the first implementation. As mentioned above, other implantation species are possible.

The implantation mask 2 shields the first layer 1 from the implantation 10. In an alternative implementation (not depicted) at least one additional shielding layer might be introduced between the implantation mask 2 and the first layer 1, which would then have to be structured to open the areas in which implantation of the first layer 1 is requested.

In a further process, the implantation mask 2 is removed, resulting in a substantially planar first layer 1. Following the removal of the second hard mask layer 2, a hard mask layer 5 (here comprising carbon), a SiON layer 6 and a second layer 3 (in this example comprising resist and an optional ARC layer) are positioned above the first hard mask layer 1 (FIG. 2C). The hard mask layer 5 and the SiON layer 6 can be introduced if the second layer 3 does not have sufficient resist budget for the etching of the via structure 11.

In a further process, the second layer 3 is used as a mask for the via structure 11 etch process. The via structure 11 is etched into the base layer 4 until the barrier layer 42 is reached. In principle the barrier layer 42 is optional.

Further, the second layer 3, the SiON layer 6 and the hard mask layer 5 are removed by an etching process, e.g., comprising a strip process with oxygen or hydrogen for a hard mask layer 5 containing carbon. The resulting layered stack is shown in FIG. 2D having a substantially planar surface.

In a further process the layered stack depicted in FIG. 2D is subjected to a wet etch comprising, for example, ammonia, potassium hydroxide, or other suitable alkaline chemistry. This etching process is selective to the first layer 1 with the implanted regions 1A. The wet etch medium etches the non-implanted part of the first layer 1, the implanted part remains (FIG. 2E). In other words, the first layer 1 is developed with regard to the implanted pattern.

In FIG. 2F the layered stack is shown after a further etch using the implanted region 1A of the first layer 1 as a mask to generate a trench structure 12. This trench etch goes into the base layer 43, here the ILD layer. The first layer 1 may comprise amorphous silicon. In case this layer is not sufficient for the etching process at least one additional layer (e.g., SiON, SiC, SiN, carbon; not depicted) can be introduced between the base layer 4 and the first layer 1. The at least one additional layer can be structured using the first layer 1.

In FIG. 2G the layered stack is shown with the remains of the first layer 1 removed. This stack is then ready for further processing, e.g. the opening of the via at the bottom by removing the barrier layer 42.

In this case, the lithography (see FIG. 2B) for the trench etching is performed before the lithography (see FIG. 2C) for the via etching.

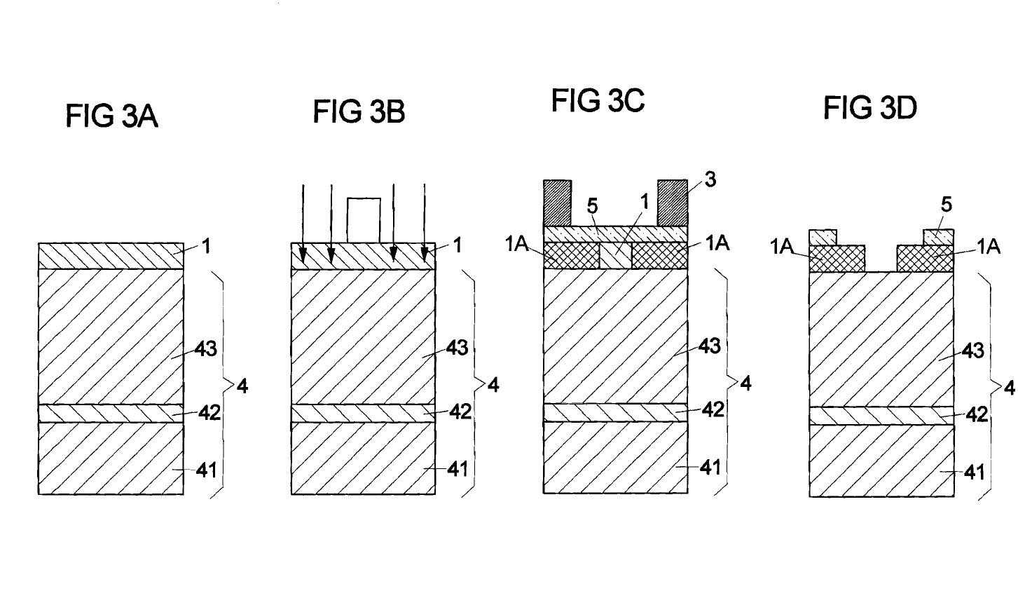

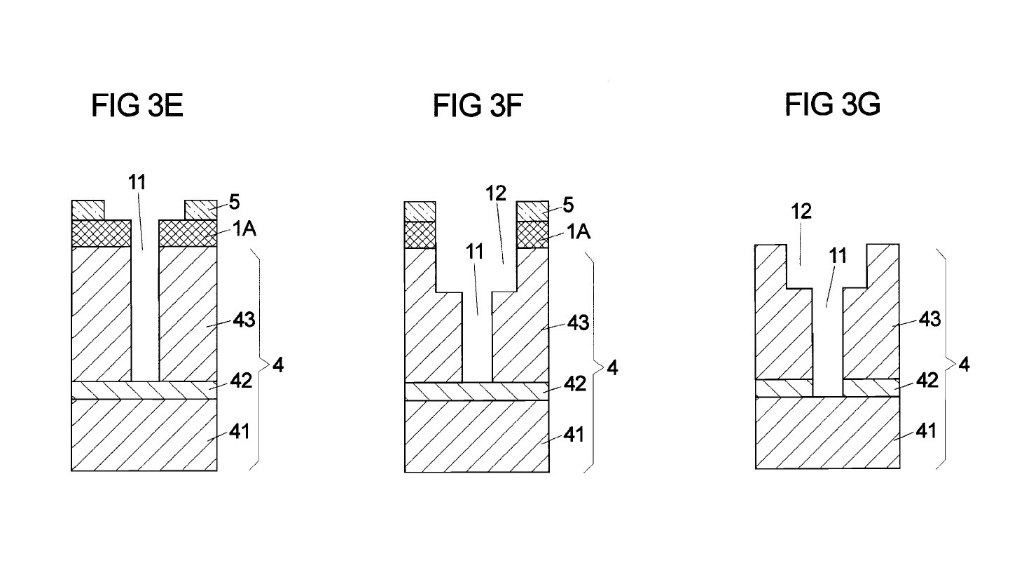

The third implementation (FIG. 3A to 3G) shows a different sequence, i.e., the lithography for the via structure 11 etching is performed before the lithography for the trench structure 12 etching.

In FIG. 3A the same starting point is used as in FIG. 2A so that reference is made to the respective description of the second implementation.

As in the second implementation, an implantation mask 2 is positioned on top of the first layer 1; the implantation mask 2 being structured afterwards. Since the mask for the via structure 11 etching is built up before the mask for the trench structure 12 etching, the implantation mask 2 is structured somewhat differently, the ridge is smaller than in the second implementation (see FIG. 3B).

In a further process the surface of the layered stack is subjected to an implantation 10 (FIG. 3B) with BF₂, like in the second implementation, so that the respective description above is applicable also.

After the implantation 10, a hard mask layer 5 as a second layer and a resist layer 3 (comprising resist and an optional ARC layer) are positioned on the first layer 1. The second layer 5 comprises, e.g., TiN or SiC. The resist layer 3 is structured which is shown in FIG. 3C.

The resist layer 3 is then used to etch the second layer 5 and the regions of the first layer 1 which were not implanted with a wet ammonia etch (see FIG. 3D). The first layer 1 can now be used to etch the via structure 11 (see FIG. 3E). Like in the second implementation, at least one additional mask layer (e.g., comprising carbon, SiN or SiON) can be introduced between the first layer 1 and the base layer 4.

The via structure 11 is etched down to the optional barrier layer 42 (see FIG. 3E). In other embodiments the via structure 11 is etched into the ILD layer 43 but not so deep that the metal layer 41 is reached.

In a further process, a trench structure 12 is etched using the second layer 5 (FIG. 3F).

In a further process the via structure is opened at the bottom by removing the barrier layer 42 at the bottom (FIG. 3G).

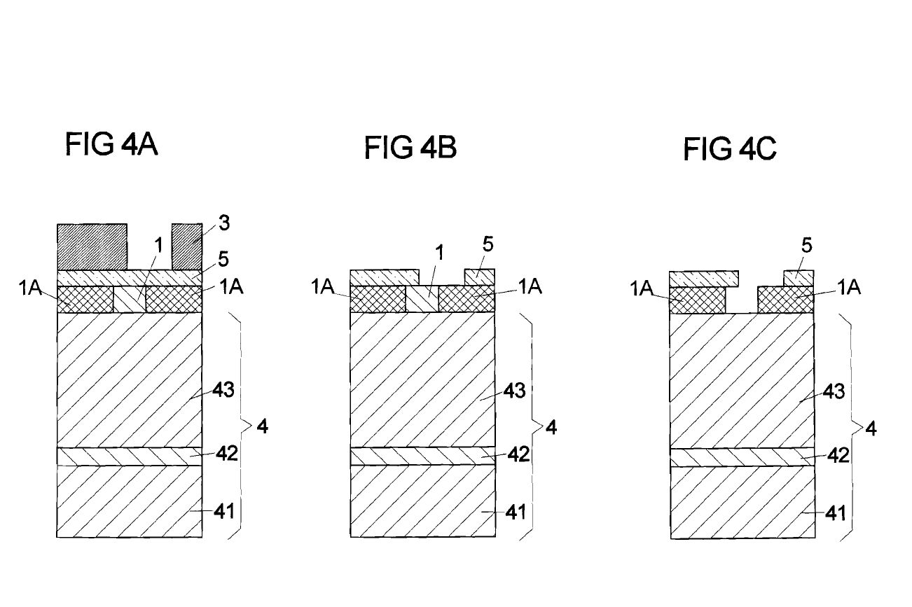

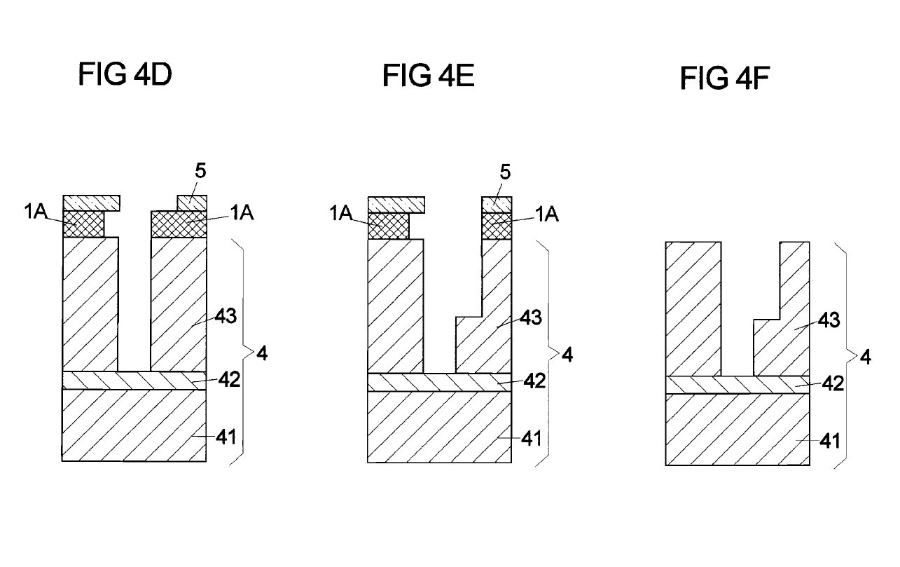

In FIG. 4A to 4E a further implementation is described which can be used in connection with one of the above described implementations.

For the sake of simplicity the starting point in this fourth implementation is a layered stack as shown in FIG. 4A. This is somewhat similar to, e.g., the cross-section shown in FIG. 3C so that reference is made to the description of the third embodiment.

The base layer 4 of the layered stack may comprise a barrier layer 42 like SiC, among other suitable materials, above the metal layer 41. The barrier layer 42 prevents the diffusion of copper into the ILD layer 43 on top of the barrier layer 42. On top of the base layer 4 a first layer 1 has been positioned which comprises non-implanted regions 1 and implanted regions 1A which have been manufactured as described in connection with FIG. 3B.

On top of the first layer 1 a second layer 5 (in this example a hard mask) has been positioned. On top of the second layer 5 a resist layer 3 has been positioned and pre-structured. As can be seen in FIG. 4A, the structuring of the resist layer 3 is slightly misaligned, since the opening (i.e., the perimeter) in the resist layer 3 partially lies over the non-implanted region 1 in the first layer 1. The consequences of this will become clear from the description below.

In FIG. 4B the layered stack is shown after a structuring of the second layer 5 and the removal of the resist layer 3. As a consequence of the misalignment of the opening in the resist layer 3, the opening in the second layer 5 overlaps the left side of the non-implanted region 1 in the first layer.

In FIG. 4C the layered stack is shown after an isotropic etching process which selectively etches the non-implanted region to develop the first layer 1 with regard to the implanted pattern. This opens the first layer 1 for the etching process of the first pattern, i.e., the via structure 11 (see FIG. 4C). The undercut of the first layer 1 may be prevented by using an anisotropic development step instead of an isotropic one.

In a further process the trench structure 12 is etched into the base layer 4 as is shown in FIG. 4D. Then the first layer 1 and the second layer 5 are removed (see FIG. 4F).

As can be seen from FIG. 4E, the smaller via structure 11 (smaller in the sense of having the smaller perimeter when seen perpendicularly from above the substrate) is contained in the larger trench structure 12, i.e., the perimeter of the first pattern is enclosed in the perimeter of the second pattern. As can be seen from FIG. 4C to 4F, the process of manufacturing those two patterns is also self-aligning.

The person skilled in the art will recognize that analog self-aligning processes are possible with other embodiments described above.

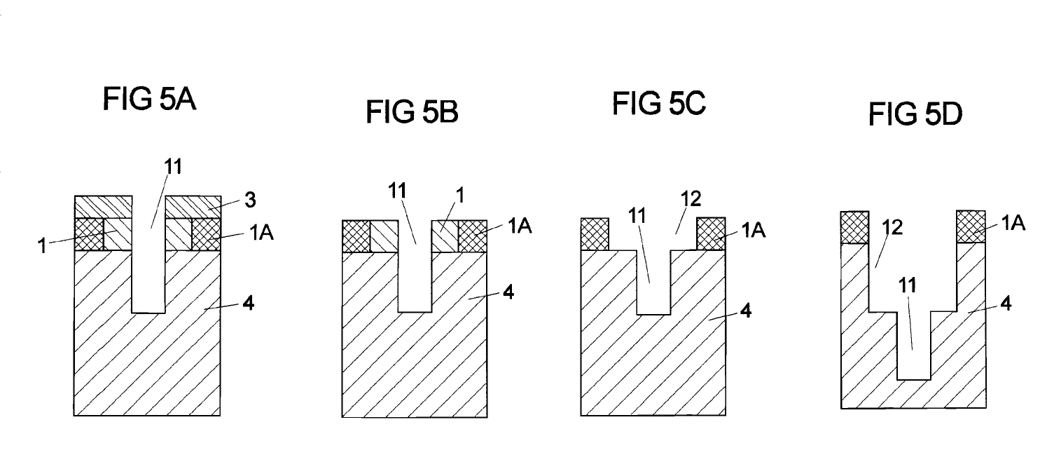

In FIG. 5A to 5D a fifth implementation is shown. This implementation can be considered as an alternative to the method described in FIG. 1A to 1D. The starting point for the fifth implementation is a layered stack as shown, e.g., in FIG. 1D. In the fifth implementation the second layer 3 is used as an etch mask to etch a first pattern, in this case, e.g., a via structure 11 into the layered stack. But unlike in the implementation shown in FIG. 1E the first pattern 11 is not etched to its final depth but to some depth shorter than that. In FIG. 5B the layered stack of FIG. 5A is shown after the removal of the second layer 3 from the first layer 1. A selective removal of implanted layer vs. non-implanted layer, e.g., by wet etching is performed. Depending on the materials used in other implementations (examples given above in connection with FIG. 1B), the inverse process is also possible, i.e., the non-implanted layer is removed selectively to the implanted layer.

As can be seen in FIGS. 1F to 1H, the implanted region 1A of the first layer 1 is used as a mask for etching a second pattern, in the present implementation a trench structure 12 (FIG. 5D). This etching is here also used to further etch the first pattern (e.g., a via structure) to its final depth.

The non implanted region of the first layer 1 is selectively removed to form a further mask comprising the implanted regions 1A.

The person skilled in the art will recognize that the etching of the first pattern in two stages is also applicable to other implementations described above.

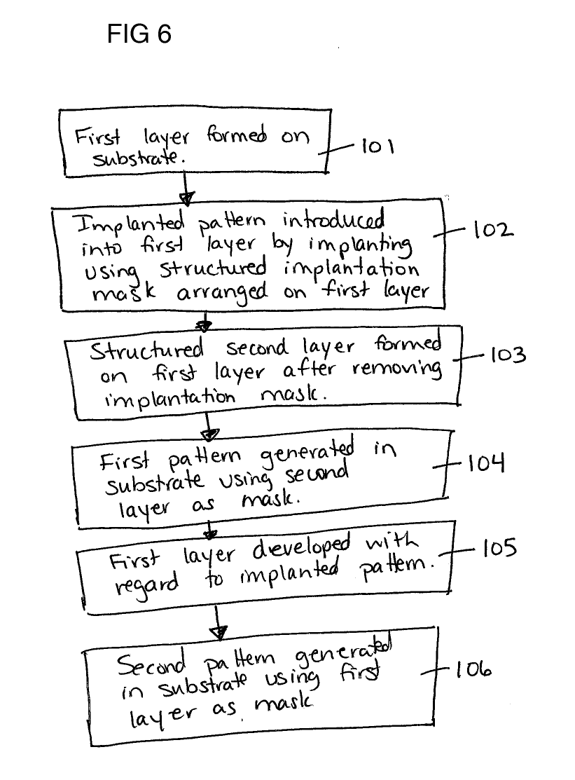

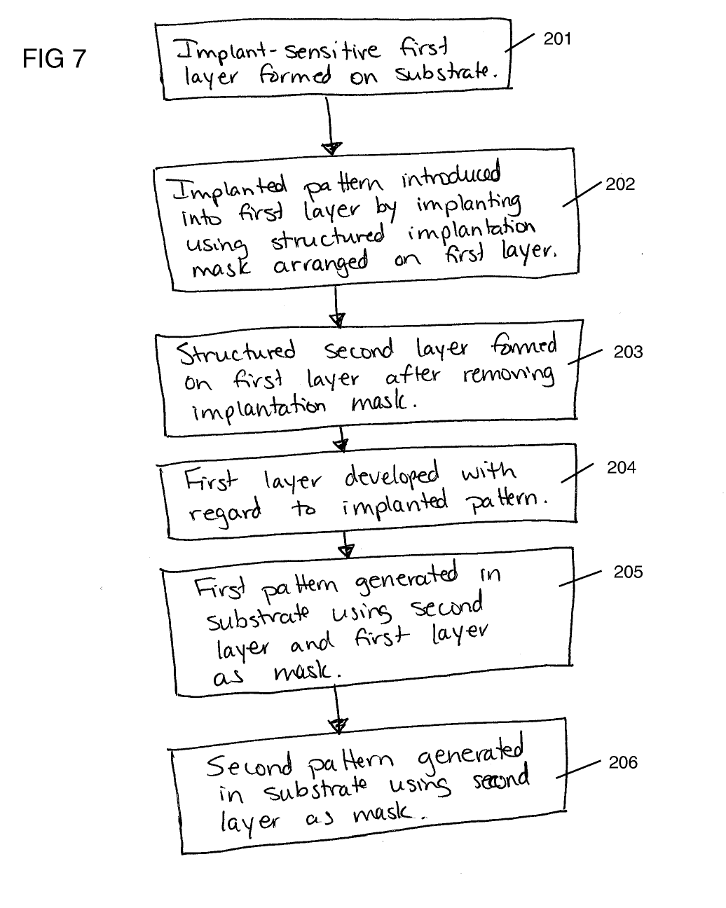

In FIG. 6 a flowchart for an implementation of the method for fabricating a semiconductor device is shown.

A first layer is formed on the substrate (101). Then an implanted pattern is introduced into the first layer by implanting using a structured implantation mask arranged on the first layer (102).

Subsequently a structured second layer is formed on the first layer after removing the implantation mask (103). Subsequently a first pattern is generated in the substrate using the second layer as a mask (104). Then the first layer is developed with regard to the implanted pattern (105) and a second pattern is generated in the substrate using the first layer as a mask (106).

In FIG. 7 a flowchart for a further implementation of the method for fabricating a semiconductor device is shown.

First, an implant-sensitive first layer is formed on the substrate (201). Then an implanted pattern is introduced into the first layer by implanting using a structured implantation mask arranged on the first layer (202). Subsequently, a structured second layer is formed on the first layer after removing the implantation mask (203). Then the first layer is developed with regard to the implanted pattern (204) and a first pattern is generated in the substrate using the second layer and the first layer as a mask (205). Subsequently, a second pattern is generated in the substrate using the second layer as a mask (206).

What is claimed is:

1. A method for fabricating a semiconductor device, the method comprising:
forming a first layer on a substrate;
introducing an implanted pattern into the first layer by implanting using a structured implantation mask arranged over the first layer;
forming a structured second layer on the first layer after removing the structured implantation mask;
generating a first pattern in the substrate using the structured second layer as a mask;
developing the first layer with regard to the implanted pattern; and
generating a second pattern in the substrate using the first layer as a mask.

2. The method of claim 1, wherein the first pattern extends into the substrate to a greater depth compared to the second pattern.

3. The method of claim 1, wherein the first pattern comprises openings and wherein the second pattern comprises lines that at least partially overlap the openings of the first pattern.

4. The method of claim 3, wherein the lines completely cover the openings.

5. The method of claim 1, wherein generating the first pattern comprises anisotropically etching the substrate to form a first structure of a first depth, and wherein the depth of the first structure is increased while generating the second pattern.

6. The method of claim 1, wherein the first layer is developed before generating the first pattern, and wherein generating the first pattern comprises anisotropically etching the substrate using the structured second layer and the developed first layer as a mask.

7. The method of claim 6, wherein generating the second pattern comprises anisotropically etching the substrate, thereby removing the structured second layer.

8. The method of claim 6, wherein generating the second pattern comprises anisotropically etching the substrate using the first layer and the structured second layer as a mask.

9. The method of claim 6, wherein the implanted pattern comprises openings, and wherein the second layer comprises lines as openings that at least partially overlap the openings of the first pattern.

10. The method of claim 9, wherein the lines completely cover the openings.

11. The method of claim 1, wherein the structured second layer is formed on a substantially planar substrate surface.

12. The method of claim 1, wherein the first and second patterns are formed in a dielectric layer and wherein the method further comprises after generating the second pattern filling the first and second pattern with a conductive material.

13. The method of claim 12, further comprising removing the conductive material by chemical-mechanical polishing to form a metallization level.

14. The method of claim 1, wherein the structured second layer comprises carbon, silicon oxynitride or silicon nitride.

15. The method of claim 1, wherein the first layer comprises silicon, silicon nitride, silicon oxynitride, titanium nitride, aluminum oxide or a high-k material.

16. The method of claim 1, wherein the implanting comprises implanting at least one species selected from the group consisting of boron, oxygen, and a noble gas.

17. The method of claim 1, wherein developing the first layer comprises contacting the substrate with at least a substance selected from the group consisting of NH₄OH, KOH, SC1, DHF and BHF.

18. The method of claim 1, wherein the structured implantation mask comprises a resist.

19. The method of claim 1, wherein the structured second layer comprises a resist.

20. The method of claim 1, wherein the substrate comprises an interlayer dielectric, a copper layer, a polycrystalline silicon layer, a silicon carbide layer, a tungsten layer or combinations thereof.

21. The method of claim 1, wherein the semiconductor device comprises a memory chip, a microprocessor, an optoelectronical device, a microelectromechanical device or a biochip.
